(19) United States
(12) Patent Application Publication
(10) Pub. No.: US 2023/0180402 A1
(43) Pub. Date: Jun. 8, 2023

(54) POWER PAD AND STRIP STRAP

(71) Applicant: Todd R' Boss, Minneapolis, MN (US)

(72) Inventor: Todd R. Boss, Minneapolis, MN (US)

(21) Appl. No.: 18/155,844

(22) Filed: Jan. 18, 2023

Related U.S. Application Data
(63) Continuation-in-part of application No. PCT/US2021/037493, filed on Jun. 15, 2021.
(60) Provisional application No. 63/055,255, filed on Jul. 22, 2020.

(51) Int. Cl. H05K 5/00; H05K 5/02

(52) U.S. Cl. CPC H05K 5/0086; H05K 5/0217; H05K 5/0247

(57) ABSTRACT

A power pad and a strip strap are disclosed. The power pad includes an array of batteries contained within a flexible, bendable housing. The housing in structured and configured to be draped over a user’s shoulder and to remain operational after a substantial number of flexing back and forth between curved and flat.

### CROSS REFERENCE TO RELATED APPLICATIONS

This application is a continuation of International Patent Application No. PCT/US2021/037493, filed Jun. 15, 2021, which claims the benefit of U. S. Provisional Pat. Application Ser. No. 63/055,255, filed on Jul. 22, 2020, both of which are incorporated herein by reference in their entireties.

### FIELD OF THE INVENTION

This disclosure relates to devices for carrying laptop computers, and more particularly, to devices that allow a user to carry and provide power to a portable electronic device.

### BACKGROUND

Computer manufacturers continue to make impressive progress in reducing the bulk and weight of laptop computers, to the delight and satisfaction of laptop users. Typically, users carry portable electronic devices from home to work or school and from one location to another. Carriers such as straps, belts or harnesses for electronic devices that make these devices easier to carry. The user can sling straps over the shoulder or can attach belts or harnesses to secure and transport the devices from one location to another.

Some carry accessories for electronic devices can also carry excess items such as spare batteries, earphones, or microphones that can be used to in conjunction with the electronic devices. In some situations, the carry accessories can include batteries that can be configured to power or recharge laptop or hand-held computers. These batteries can include one or more power cables that can be embedded inside or attached to the inner part of a strap as disclosed, for example, in PCT Patent Application Publication, WO 2019/194978 A1 (Boss et al.).

### SUMMARY

What is needed is a power pad that is a component that can be utilized as a part of a strap, belt, or harness for carrying electronic devices such as laptop computers or handheld computers. The disclosed power pad can also be contemplated to be useful for camera users and other users who carry portable electronics like phones, drones, etc. The power pad is an article that can be attached to a carrying strap or harness and can fit over the shoulder of a user. The power pad can be useful for charging or recharging the electronic device and can function as a cushioning pad that conforms to the shoulder geometry. Embedded into the power pad is a flexible battery that can conform, with the power pad, to the shape of the user’s shoulder.

In one aspect, a power pad is disclosed that includes a flexible housing. The power pad can be structured and configured to remain in working order (electrically connected) when the power pad is toggled (bent and flexed) back and forth from a curved shape to a flat shaped. The power pad can be toggled back and forth over the lifetime of the power pad and can withstand bending and flexing for over 100, over 500, over 1000, over 10,000 times or more.

### BRIEF DESCRIPTION OF THE DRAWINGS

The following description should be read with reference to the drawings. The drawings, which are not necessarily to scale, depict examples and are not intended to limit the scope of the disclosure. The disclosure may be more completely understood in consideration of the following description and with respect to various examples in connection with the accompanying drawings, in which:

FIG. 1 is a side view of an embodiment of a disclosed power pad and strip strap positioned over a user’s shoulder;

FIG. 1A is a side exploded view of the power pad illustrated in FIG. 1;

FIG. 2 is a perspective side view of an embodiment of a disclosed power pad in a conformation that will fit over a user’s shoulder;

FIG. 3 is a top view of the embodiment of the disclosed power pad illustrated in FIG. 2;

FIG. 4 is a perspective view of an embodiment of a strip strap according to this disclosure that includes a wire or cable;

FIG. 5 is a top view of the strip strap illustrated in FIG. 4 without wire or cable; and

FIG. 6 is a side perspective view of a disclosed power pad and strip strap according to the present disclosure.

In the present application,
the term, “array of batteries” refers to one or more batteries hooked together in series or parallel;
the term, “curved shape” refers to a configuation that substantially deviates from a straight line or a flat shape;
the term “toggle” refers to the back and forth repeated movement of a flexible object.

### DETAILED DESCRIPTION

This disclosure relates to devices for carrying laptop computers, and more particularly, laptop carrying straps. Various embodiments are described in detail with reference to the drawings, in which like reference numerals may be used to represent like parts and assemblies throughout the several views. Reference to various embodiments does not limit the scope of the systems and methods disclosed herein. Examples of construction, dimensions, and materials may be illustrated for the various elements, and those skilled in the art will recognize that many of the examples provided have suitable alternatives that may be utilized. Any examples set forth in this specification are not intended to be limiting and merely set forth some of the many possible embodiments for the systems and methods. It is understood that various omissions and substitutions of equivalents are contemplated as circumstances may suggest or render expedient, but these are intended to cover applications or embodiments without departing from the spirit or scope of the disclosure. Also, it is to be understood that the phraseology and terminology used herein are for the purpose of description and should not be regarded as limiting.

Persons of ordinary skill in arts relevant to this disclosure and subject matter hereof will recognize that embodiments may comprise fewer features than illustrated in any individual embodiment described by example or otherwise contemplated herein. Embodiments described herein are not meant to be an exhaustive presentation of ways in which various features may be combined and/or arranged. Accordingly, the embodiments are not mutually exclusive combinations of features; rather, embodiments can comprise a combination of different individual features selected from different individual embodiments, as understood by persons of ordinary skill in the relevant arts. Moreover, elements described with respect to one embodiment can be implemented in other embodiments even when not described in such embodiments unless otherwise noted. Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended. Furthermore, it is intended also to include features of a claim in any other independent claim even if this claim is not directly made dependent to the independent claim.

A power pad and a strip strap are disclosed herein. Although each of these is a separate component, a device is contemplated that can include one or both of these components. The contemplated device or combined devices can be a stand-alone mobile source of power that can be used to support a portable electronic device such as a camera, a smart phone, a laptop computer, or a smart tablet. Other potential portable electronic devices within the scope of this disclosure can include a portable breast pump, or a powered medical device such as an infusion pump or a continuous monitor of a medical condition (such as glucose level or another chemical indicator) that can be portable and worn on the user. In some embodiments, the powered medical device can also include a portable blood pressure monitor. The power pad can be used in combination with (or without) the strip strap described below to complete a circuit. Alternatively, a user can carry necessary power cabling to attach a portable electronic device to the power pad.

In some embodiments, when the power pad can be used in combination with the strip strap, the power pad can be disposed upon and/or attached to the disclosed strip strap. Exemplary attachments can include permanent attachments or removably fastened attachments. For example, the power pad can be formed as one piece when the strip strap is formed. In other embodiments, the power pad can be sewed, welded, glued, cemented, or otherwise permanently attached to the strip strap. In some other embodiments, the power pad can be removably fastened to the strip strap using repositionable fasteners such as snaps, hooks, hook and loop fasteners, belts, or any other fasteners that can attach the power pad to the strip strap in a removeable fashion.

The disclosed power pad includes a battery or an array of batteries and a housing that can include the battery. The battery can be an external battery similar to a common rechargeable consumer external battery. The disclosed battery or array of batteries can be flexible or bendable across an arc, such as a user’s shoulder, rather than rigid. The flexibility or bendability of the external battery can allow the battery or array of batteries to lay over a user’s shoulder and to remain in working condition while flexing back and forth from curved to flat and back again. Typical batteries useful in that disclosed power pad can include consumer batteries useful and electronic devices. Such batteries include AA or AAA batteries, battery buttons, lithium-ion rechargeable batteries, NiCd rechargeable batteries, or any other batteries useful in portable electronic devices.

The disclosed power pad and strap can include a flexible housing. The power pad can be structured and configured to remain in working order (electrically connected) when the power pad is toggled (bent and flexed) back and forth from a curved shape (when, for example, draped over the shoulder of a user) to a flat shape. The power pad can be toggled back and forth over the lifetime of the power pad and can withstand bending and flexing for over 100, over 500, over 1000, over 10,000 times or more.

The flexible housing of the power pad can be made of flexible and bendable materials. For example, the flexible housing can include soft, stretchable materials such as elastic or foam, can be stretchable (low modulus) or otherwise constructed. In many embodiments, the flexible housing can include several different materials attached together. For example, the flexible housing can include fabric on the outer sides which is bunched together in an accordion shape and can have a flexible material contained within.

Batteries in the disclosed power pad can be located on or in a flexible housing. Typically, the flexible housing is permanently or removably attachable to a strip strap as described below. The disclosed housing can detachable. It can be constructed with a breathable, water-resistant fabric that can affix using a removeable or permanent fastener to form a reliable connection to a cross-body strap—thereby becoming a shoulder pad. The shoulder pad can provide a soft interface with the user’s body, thus stabilizing the strap when power input/output connections as made. The disclosed power pad can include one or more ports. The ports can be structured and configured to attach wires or cables that can allow power to flow from the batteries in the power pad to a distant electronic device. In some configurations, the ports can be standard ports used in the electronic display industry and can include, for example, type A, B, or C USB ports; serial ports, parallel ports; PS/2 ports; universal serial bus ports; VGA ports; HDMI ports; DVI ports; or any other multipin ports useful for electronic devices. The ports can be male or female ports. In some embodiments, the disclosed power pad can include additional electronics other than a battery or battery pack. For example, the disclosed power pad can include, but is not limited to such devices such as a smart phone, a portable audio or video player (such as, for example, an iPod), a GPS device, a smart watch, a health tracker, or a distance tracker. In such embodiments, a wire or cable can be attached to one or more of the ports to transmit information from a device in the power pad to an external source such as, but not limited to, an earphone or earbud.

The disclosed strip strap can provide cabling to or from a disclosed power pad. The disclosed strip strap can be used in combination with any portable device as disclosed elsewhere in this application. In some embodiments, the strip strap can include a power cable. The power cable can be attached to or embedded into the disclosed strip strap. By embedded, it is meant that the power cable can be completely enclosed in a compartment in the strip strap. Alternatively, the power cable can be at least partially enclosed in a compartment in the strip strap. Or, the disclosed strip strap can include fastening features such as loops or sleeves through which a power cable can be threaded. The power cable may be removeable or replaceable from the strip strap or it may be permanently incorporated into the strip strap by sewing, gluing, or otherwise attaching the power cord to the strip strap by methods know to those of ordinary skill in the art. The cable can connect to the strap through a series of fabric tunnels, tapes, or clips that hold the cable securely in place while allowing it to bend with normal use of the strip strap as it is carried by a user. In some embodiments, the ends of the power cable can be tucked into the strip strap. Or, the ends of the power cable can be exposed for ready connection to a disclosed power pad on the top end, or to an electronic device at the bottom end.

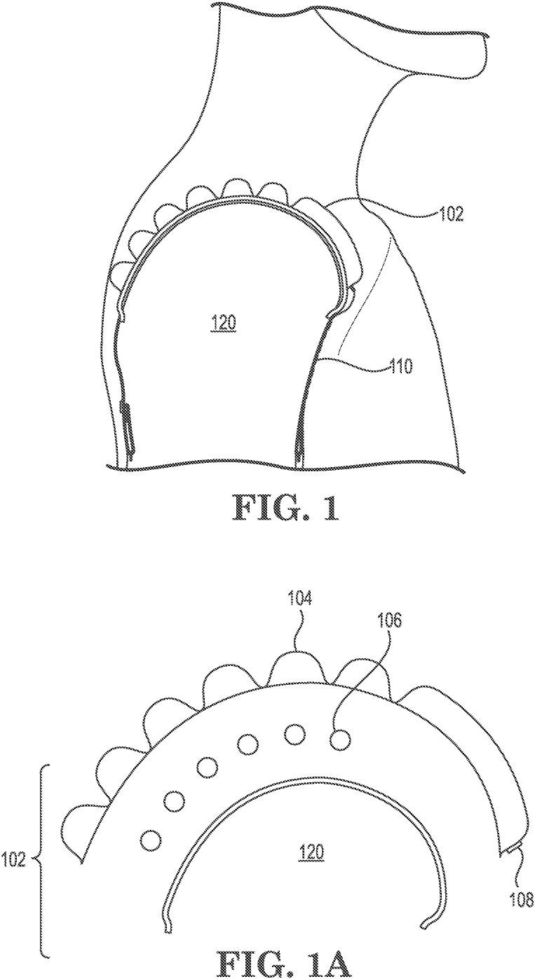

FIG. 1 is a side view of an embodiment of a disclosed power pad and strip strap positioned over a user’s shoulder. FIG. 1 shows power pad 102 disposed upon strip strap 110 which is in turn draped over a user’s shoulder 120. FIG. 1A is a side exploded view of the power pad illustrated in FIG. 1. Power pad 102 includes one or more batteries or an array of batteries hooked together in parallel or series that are disposed upon shoulder 120 when power pad 102 is worn. Power pad 102 also can include housing 104 that can contain batteries 106. Housing 104 can be comprised of a series of individual battery housings, wherein one battery is stored per battery housing, as illustrated in FIG. 1A. For example, for a power pad 102 having six batteries 106, there may be six battery housings that comprise housing 104. Each battery housing may be approximately a half-cylinder such that it has a relatively flat bottom and an arcuate, long dome, as illustrated in FIG. 1. Additionally, each battery housing may be completely contained and separate from the other battery housings but may allow for internal electronics to wire together to allow the batteries to be connected in parallel or in series. Alternatively, batteries 106 may all be stored in one continuous housing. Power pad 102 also includes ports 108 (shown as female ports in the illustrative embodiment).

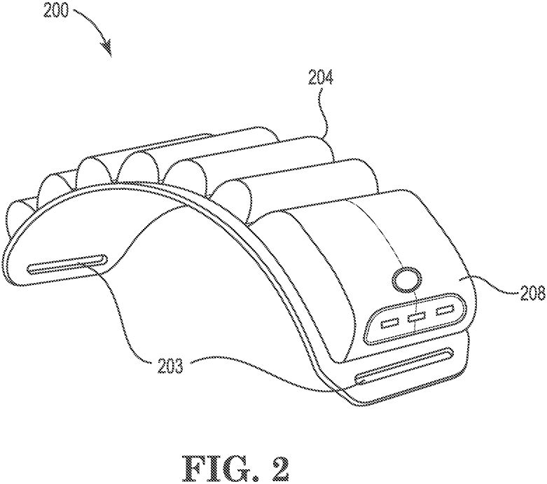

FIG. 2 is a perspective side view of an embodiment of a disclosed power pad in a conformation that will fit over a user’s shoulder. Power pad 200 includes housing 204 that includes an array of batteries (not shown but inside of housing). Power pad 200 also includes ports 208 to allow connection of wires. Also shown in the illustrated embodiments are slots 203 that allow power pad 200 to be removably attached to a carrying strap such as the disclosed strip strap.

As with power pad 104, housing 204 may be comprised of a series of a series of individual battery housings, wherein one battery is stored per battery housing. Each battery housing may be approximately a half-cylinder such that it has a relatively flat bottom and an arcuate, long dome, as illustrated in FIG. 2. Additionally, each battery housing may be completely contained and separate from the other battery housings but may allow for internal electronics to wire together to allow the batteries to be connected in parallel or in series. Alternatively, batteries may all be stored in one continuous housing.

Ports 208 may include two or more ports that are part of a port housing. The port housing may be in line with, and on one end of, the series of battery housings, as illustrated in FIG. 2. The port housing may be slightly larger than the battery housings. For example, it may be the same length, so as to fit across the strap, but of a longer width. The width may be two, three, or four times wider than the width of the battery housings. Ports 208 may be located on an end of the port housing opposite housing 204, as illustrated in FIG. 2.

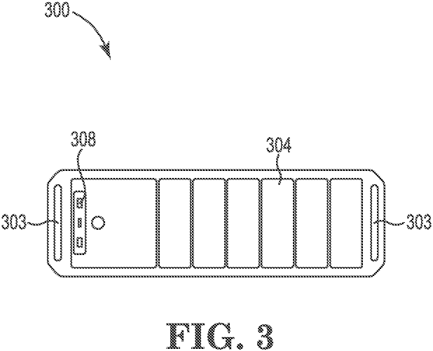

FIG. 3 is a top view of the embodiment of the disclosed power pad illustrated in FIG. 2. FIG. 3 shows power pad 300 that includes housing 304 (that includes an array of batteries that are not visible in FIG. 3). The overall shape of power pad 300 may be approximately rectangular. Power pad 300 includes ports 308 and slots 303.

As with power pad 104 and 200, housing 304 of power pad 300 may be comprised of a series of a series of individual battery housings, wherein one battery is stored per battery housing. Each battery housing may be approximately a half-cylinder such that it has a relatively flat bottom and an arcuate, long dome. Additionally, each battery housing may be completely contained and separate from the other battery housings but may allow for internal electronics to wire together to allow the batteries to be connected in parallel or in series. Alternatively, batteries may all be stored in one continuous housing.

Additionally, ports 308 may include two or more ports that are part of a port housing. The port housing may be in line with, and on one end of, the series of battery housings, as illustrated in FIG. 3. The port housing may be slightly larger than the battery housings. For example, it may be the same length, so as to fit across the strap, but of a longer width. The width may be two, three, or four times wider than the width of the battery housings. Ports 308 may be located on an end of the port housing opposite housing 304, as illustrated in FIG. 3.

Slots 303 may be on opposite ends of power pad 300. More specifically, slots 303 may be comprised of two slots. A first slot may be located on an end of power pad 300 near ports 308. A second slot may be located on an opposite end of power pad 300 near the final battery housing of housing 304. Slots 303 may be slightly shorter and narrower than the battery housings and port housing, as illustrated in FIG. 3.

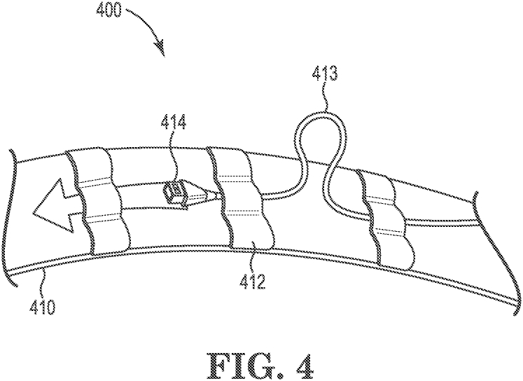

FIG. 4 is a perspective view of an embodiment of a strip strap according to this disclosure that includes a wire or cable. Strip strap 400 includes strap 410. Strap 410 is structured and configured be attachable to an electronic device such as a smart phone, a laptop computer, or another electronic display device. Strip strap 400 has one or a plurality of fastening loops 412 through which wire or cable 413 can be secured. Cable 413 can include electronic connector port 414 (shown as male port in the illustrated embodiment). Fastening loops 412 may be comprised of several rows and columns, as illustrated in FIG. 4. More specifically, fastening loops 412 may be comprised of three rows and three columns. Each row may have separate loops that are connected together, and each column may be separated by space on the strap 410. Therefore, cable 413 can be secured across three rows and within a single column, as illustrated in FIG. 4, and portions of cable 413 can be exposed between rows. This enables the number of columns to align with the number of ports (not shown in FIG. 4). For example, if there are three ports, there can be three columns such that three cables can be simultaneously secured to strip strap 400 and connected to a power pad.

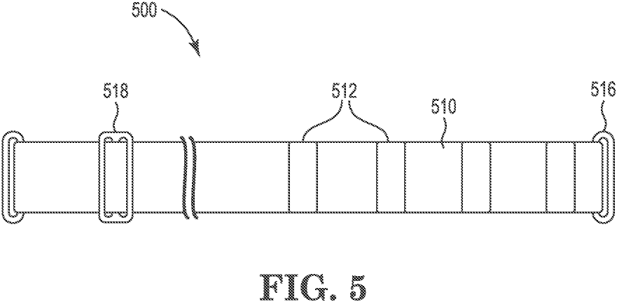

FIG. 5 is a top view of the strip strap illustrated in FIG. 4 without a wire or cable attached. Strip strap 500 includes additional features not shown in FIG. 4. Strip strap 500 includes fastening loops 512 attached to strap 510. Fastening loops 512 can be used to attach a wire or cable (shown in FIG. 4 but not in FIG. 5). Strip strap 500 includes two strap loops 516 attached to each end of strip strap 500. Strap loops 516 can be used to attach strip strap 500 to one or more other electronic devices and can be used to carry the device as well as power it (if a power carrying wire or cable is attached). Adjustment 518 can be used to lengthen or shorten strip strap 500 to adjust to the user’s needs.

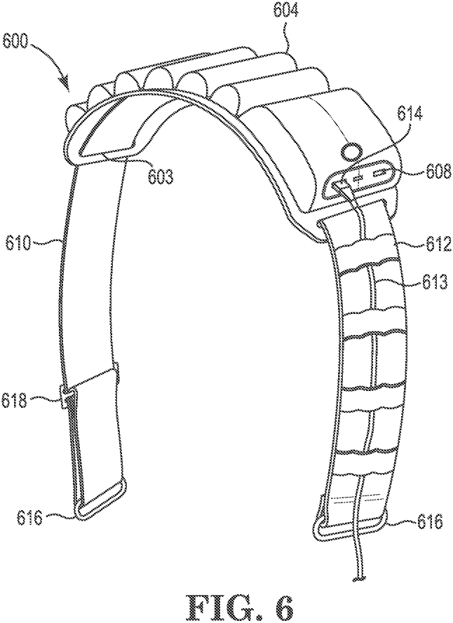

FIG. 6 is a side perspective view of a disclosed power pad and strip strap according to the present disclosure. Power pad and strip strap 600 includes power pad 604 as shown in earlier illustrations. Power pad 604 can include an array of batteries (not shown but inside of housing). As above, the housing of power pad 604 may be comprised of a series of individual battery housings, wherein one battery is stored per battery housing. Each battery housing may be approximately a half-cylinder such that it has a relatively flat bottom and an arcuate, long dome, as illustrated in FIG. 6. Additionally, each battery housing may be completely contained and separate from the other battery housings but may allow for internal electronics to wire together to allow the batteries to be connected in parallel or in series. Alternatively, batteries may all be stored in one continuous housing.

Power pad 604 also includes female port 608 to which power cord 613 is connected through male port 614. Port 608 may be comprised of more than one port that are part of port housing. For example, as illustrated in FIG. 6, port 608 may include three ports. The port housing may be in line with, and on one end of, the series of battery housings, as illustrated in FIG. 6. The port housing may be slightly larger than the battery housings. For example, it may be the same length, so as to fit across the strap, but of a longer width. The width may be two, three, or four times wider than the width of the battery housings. Ports 608 may be located on an end of the port housing opposite the housing, as illustrated in FIG. 6. Additionally, as described above, more than one power cord 613 may be connected and may contain male port 614. For example, there may be three power cords 613, each with a male port 614.

Strap 610 has one or a plurality of fastening loops 612 through which wires or cables, such as power cord 613, can be secured. Fastening loops 612 may be comprised of several rows and columns, as illustrated in FIG. 6. More specifically, fastening loops 612 may be comprised of four rows and three columns. Each row may have separate loops that are connected together, and each column may be separated by space on the strap 610. Therefore, cable 613 can be secured across a plurality of rows and within a single column, as illustrated in FIG. 6, and portions of cable 613 can be exposed between rows. This enables the number of columns to align with the number of ports 608. For example, if there are three ports, there can be three columns such that three cables can be simultaneously secured to strip strap 610 and connected to power pad 604.

Power pad 604 also includes slots 603 through which strap 610 is threaded. These slots 603 allow power pad 604 to be removably attached to strap 610. Slots 603 may be on opposite ends of power pad 604. More specifically, slots 603 may be comprised of two slots. A first slot may be located on an end of power pad 604 near ports 608. A second slot may be located on an opposite end of power pad 604 near the final battery housing of housing. Slots 603 may be slightly shorter and narrower than the battery housings and port housing, as illustrated in FIG. 6. Strap 610 can thread through a first slot 603, run along a bottom surface of power pad 604, and thread back out through the second slot 603. Strap 610 can include two strap strips 616 on opposing ends to attach an electronic device (not shown). Also illustrated is adjustment 618 for use in lengthening or shortening strip strap 610 as needed.

Various modifications and alterations to this disclosure will become apparent to those skilled in the art without departing from the scope and spirit of this disclosure. It should be understood that this disclosure is not intended to be unduly limited by the illustrative embodiments set forth herein and that such embodiments are presented by way of example only with the scope of the disclosure intended to be limited only by the claims set forth herein as follows. All references cited in this disclosure are herein incorporated by reference in their entirety.

What is claimed is:

1. A power pad comprising:
a flexible housing;
an array of batteries disposed within the flexible housing; and
a strip strap,
wherein the power pad is structured and configured to remain in working order when toggled back and forth from curved shape to a flat shape.

2. A power pad according to claim 1, wherein the power pad is configured to fit snugly over a shoulder.

3. A power pad according to claim 2, wherein the power pad comprises cushioning pads.

4. A power pad according to claim 1, further comprising a portable electronic device in electronic communication with the array of batteries.

5. A power pad according to claim 4, wherein the portable electronic device comprises a camera, a smart phone, a laptop computer, a smart tablet, a portable breast pump, a GPS device, a smart watch, a portable audio or video player, a health tracker, a distance tracker, or a powered medical device.

6. A power pad according to claim 5, wherein the powered medical device comprises a glucose level monitor or a blood pressure monitor.

7. A power pad according to claim 4, wherein the power pad comprises one or more ports structured and configured to attach wires or cables to a portable electronic device.

8. A power pad according to claim 7, wherein the ports comprise standard ports used in the electronic display industry.

9. A power pad according to claim 8, wherein the standard ports comprise type A, B, or C USB ports; serial ports; parallel ports; PS/2 ports; universal serial bus ports; VGA ports; HDMI ports; DVI ports; or multipin ports.

10. A power pad according to claim 7, wherein one or more ports of the power pad are attached to an earphone or earbud.

11. A power pad according to claim 1, wherein the strip strap comprises a power cable.

12. A power pad according to claim 11, wherein the strip strap comprises loops or sleeves.

13. A power pad according to claim 11, wherein the power cable is attached to or embedded in a compartment in the strip strap.

14. A power pad according to claim 11, wherein the power cable is attached to the strip strap.

15. A power pad according to claim 11, wherein the strip strap comprises a wire attached to one or more ports.
